(19) United States
(12) Patent Application Publication
(10) Pub. No.: US 2024/0360310 A1
(43) Pub. Date: Oct. 31, 2024

(54) RESIN COMPOSITION, SEMICONDUCTOR DEVICE, AND METHOD FOR PRODUCING SEMICONDUCTOR DEVICE

(71) Applicant: NAMICS CORPORATION, Niigata-shi, Niigata (JP)

(72) Inventors: Hirotatsu IKARASHI, Niigata (JP); Masaki YOSHIDA, Niigata (JP); Toshiyuki SATO, Niigata (JP); Shin TERAKI, Niigata (JP)

(21) Appl. No.: 18/689,720

(22) PCT Filed: Sep. 15, 2022
(86) PCT No.: PCT/JP2022/034526

§ 371 Date: Mar. 6, 2024

(30) Foreign Application Priority Data
Oct. 4, 2021 (JP) 2021-163438

(51) Int. Cl. C08L 71/12; C08L 53/02; H01L 23/29

(52) U.S. Cl. CPC C08L 71/126; C08L 53/02; H01L 23/293; C08L 2203/206

(57) ABSTRACT

Provided are a resin composition for a semiconductor device of a wafer level chip size package type, which exhibits excellent high-frequency properties, and can form a coating film which has a thickness that has less unevenness, and is unlikely to cause warpage of the semiconductor substrate, a semiconductor device using the same, and a method for producing a semiconductor device. A resin composition for a semiconductor device of a wafer level chip size package type, the resin composition comprising (A) a modified polyphenylene ether resin having an unsaturated double bond at the end thereof, (B) an elastomer having a butadiene skeleton, and optionally (C) a solvent, a semiconductor device using the same, and a method for producing a semiconductor device.

### CROSS REFERENCE TO RELATED APPLICATIONS

This application is a 371 U.S. National Phase of International Application No. PCT/JP2022/034526, filed on Sep. 15, 2022, which claims priority to Japanese Patent Application No. 2021-163438, filed Oct. 4, 2021. The entire disclosures of the above applications are incorporated herein by reference.

### BACKGROUND

### Technical Field

The present invention relates to a resin composition, a semiconductor device using the same, and a method for producing a semiconductor device.

### Background Art

Electronic devices are being reduced in the size and weight and improved in the functions, and hence a semiconductor package used in the electronic devices is required to be further downsized and more lightweight and to be mounted on a printed circuit board with high mounting density. Under the circumstances, a technique for semiconductor package called a wafer level chip size package (frequently referred to as “WL-CSP”) has been proposed. The wafer level chip size package indicates a semiconductor package which has not been subjected to internal wiring by bonding wire and thus has left part of a semiconductor substrate (silicon wafer) exposed, and which has a size almost equivalent to that of the semiconductor substrate.

For example, JP 2017-92152 A and JP 2010-192938 A disclose a WL-CSP. The WL-CSP comprises, on a semiconductor substrate (silicon wafer), a multilayer structure having an electrode, an insulating layer, a redistribution layer, an encapsulation resin layer, and the like, and an external terminal, such as a solder pump.

As the speed of data transmission is increasingly becoming higher and the capacity of the data transmitted is being increased, electronic parts are required to have high frequency properties, and a WL-CSP used in the electronic parts is also needed to have high frequency properties. For example, in a high frequency region, specifically, in the frequency region of 1 GHz to 10 GHz, the WL-CSP is required to have excellent electrical properties (low permittivity (ε) and low dielectric loss tangent (tanδ)).

In the production of WL-CSP, in some cases, an interlayer dielectric film is formed by applying a resin composition onto a semiconductor substrate (silicon wafer) using a spin coater which is of a rotary type.

However, depending on the type of the resin material used in the resin composition, the application of the resin composition to a semiconductor substrate using a spin coater poses a problem in that a uniform coating film cannot be formed on the semiconductor substrate or in that, after the application of the resin composition, the semiconductor substrate suffers warpage due to shrinkage of the resin composition being cured, or the like.

Accordingly, an object of the present invention is to provide a resin composition for a semiconductor device of a wafer level chip size package type, which exhibits excellent high-frequency properties, and even when applying the composition to a semiconductor substrate using a spin coater, can form a coating film which has a thickness that has less unevenness, and is unlikely to cause warpage of the semiconductor substrate, a semiconductor device using the same, and a method for producing a semiconductor device.

### SUMMARY

A means for solving the above-mentioned problems is as described below, and the present invention encompasses the following embodiments.

[1] A resin composition for a semiconductor device of a wafer level chip size package type, the resin composition comprising:
(A) a modified polyphenylene ether resin having an unsaturated double bond at the end thereof, and
(B) an elastomer having a butadiene skeleton.

[2] The resin composition according to item [1] above, wherein the modified polyphenylene ether resin (A) having an unsaturated double bond at the end thereof comprises a modified polyphenylene ether resin represented by the following formula (1):

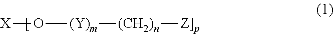

in which X represents a p-valent unsubstituted or substituted aromatic hydrocarbon group,

Y represents an unsubstituted or substituted phenol repeating unit represented by the following formula (2):

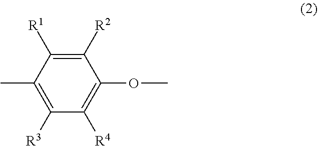

in which each of R¹ to R⁴ independently represents a hydrogen atom, an alkyl group, an alkenyl group, an alkynyl group, or an alkenylcarbonyl group,

Z is a terminal functional group having a carbon-carbon double bond, and represents a vinyl group, a vinylene group, an (meth)acryloyl group represented by the following formula (3) or a styrene group represented by the following formula (4):

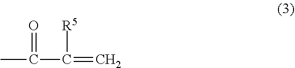

in which R⁵ represents a hydrogen atom or an alkyl group,

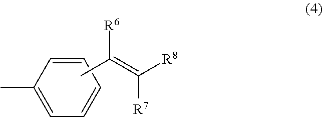

in which each of R⁶ to R⁸ independently represents a hydrogen atom, an alkyl group, an alkenyl group, or an alkynyl group,
m represents an integer of 1 to 100,
n represents an integer of 0 or 1 to 6, and
p represents an integer of 1 to 4.

[3] The resin composition according to item [1] or [2] above, in which the elastomer (B) having a butadiene skeleton comprises at least one member selected from the group consisting of a styrene/butadiene/styrene copolymer, a styrene/butadiene/butylene/styrene copolymer, a butadiene polymer, a styrene/butadiene copolymer, and an acrylonitrile/butadiene copolymer.

[4] The resin composition according to any one of items [1] to [3] above, in which the modified polyphenylene ether resin (A) having an unsaturated double bond at the end thereof comprises at least one member selected from the group consisting of a modified polyphenylene ether resin represented by the following formula (5) and a modified polyphenylene ether resin represented by the following formula (6):

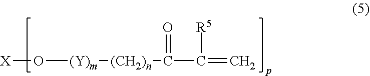

in which R⁵ represents a hydrogen atom or an alkyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents an integer of 0 or 1 to 6, and
p represents an integer of 1 to 4,

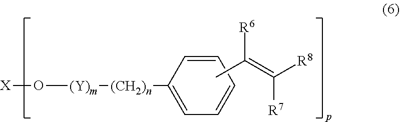

in which each of R⁶ to R⁸ independently represents a hydrogen atom, an alkyl group, an alkenyl group, or an alkynyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents an integer of 0 or 1 to 6, and
p represents an integer of 1 to 4.

[5] The resin composition according to any one of items [1] to [4] above, in which the elastomer (B) having a butadiene skeleton comprises at least one member selected from the group consisting of a styrene/butadiene/styrene block copolymer represented by the following formula (7) and an acrylonitrile/butadiene copolymer represented by the following formula (8):

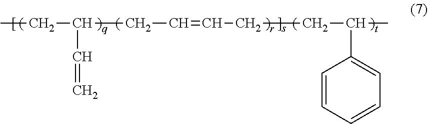

in which q and r represent an integer of 0 or 1, with the proviso that at least one of q and r is not 0, s represents an integer of 1 to 1,200, and t represents an integer of 1 to 1,000,

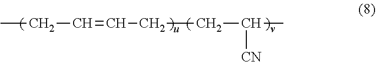

in which u represents an integer of 1 to 1,200, and v represents an integer of 1 to 1,000.

[6] The resin composition according to any one of items [1] to [5] above, in which the modified polyphenylene ether resin (A) having an unsaturated double bond at the end thereof comprises a modified polyphenylene ether resin represented by the formula (6) above, and in which the elastomer (B) having a butadiene skeleton comprises a styrene/butadiene/styrene copolymer represented by the formula (7) above.

[7] The resin composition according to any one of items [1] to [6] above, further comprising (C) a solvent.

[8] The resin composition according to item [7] above, which has a first viscosity in the range of from 300 to 4,000 mPa·s, as measured at 25° C. and at 10 rpm using a rotational viscometer.

[9] The resin composition according to item [8] above, which has a second viscosity in the range of from 500 to 4,200 mPa·s, as measured at 25° C. and at 1 rpm using a rotational viscometer, and which has a thixotropy index TI of 0.8 to 1.2, in terms of the ratio of the second viscosity to the first viscosity.

[10] The resin composition according to any one of items [1] to [9] above, in which the mass ratio of the component (A) and the component (B) is in the range of 10:90 to 80:20.

[11] The resin composition according to any one of items [7] to [10] above, in which the mass ratio of the total of the components (A) and (B) and the component (C) is in the range of 5:95 to 80:20.

[12] A semiconductor device of a wafer level chip size package type, the semiconductor device comprising a semiconductor substrate, an electrode disposed on the semiconductor substrate, a wiring electrically connected to the electrode, an external terminal electrically connected to the electrode through the wiring, and an interlayer dielectric film for encapsulating the side of the semiconductor substrate on which the electrode and the wiring are disposed, in which the interlayer dielectric film is disposed so as to be in contact with the wiring, and is formed using the resin composition according to any one of items [1] to [11] above.

[13] The semiconductor device according to item [12] above, which comprises at least two layers of a first interlayer dielectric film for encapsulating the semiconductor substrate side of the wiring and a second interlayer dielectric film for encapsulating the side of the wiring opposite to the semiconductor substrate.

[14] The semiconductor device according to item [12] or [13] above, wherein one film of the interlayer dielectric film, the first interlayer dielectric film, or the second interlayer dielectric film has a thickness in the range of from 3 to 20 μm.

[15] A method for producing a semiconductor device of a wafer level chip size package type, the method comprising:
providing a resin composition in a liquid state, which comprises the following components (A) to (C):
(A) a modified polyphenylene ether resin having an unsaturated double bond at the end thereof,
(B) an elastomer having a butadiene skeleton, and
(C) a solvent;
applying dropwise the resin composition onto a semiconductor substrate and spinning the semiconductor substrate on the vertical axis using a spin coater to apply the resin composition in a liquid state to the semiconductor substrate; and
curing the resin composition in a liquid state to form an interlayer dielectric film.

[16] The method for producing a semiconductor device according to item [15] above, in which the spin coater has a rotational speed of 1,000 to 3,000 rpm, and the time of rotation is 5 to 30 seconds.

[17] The method for producing a semiconductor device according to item [15] or [16] above, in which the resin composition in a liquid state has a first viscosity of 300 to 4,000 mPa·s, as measured at 25° C. and at 10 rpm using a rotational viscometer.

[18] The method for producing a semiconductor device according to item [17] above, in which the composition in a liquid state has a second viscosity of 500 to 4,200 mPa·s, as measured at 25° C. and at 1 rpm using a rotational viscometer, and has a thixotropy index TI of 0.8 to 1.2, in terms of the ratio of the second viscosity to the first viscosity.

[19] The method for producing a semiconductor device according to any one of items [15] to [18] above, in which the modified polyphenylene ether resin (A) having an unsaturated double bond at the end thereof comprises a polyphenylene ether resin represented by the formula (1) above,
and in which the elastomer (B) having a butadiene skeleton comprises at least one member selected from the group consisting of a styrene/butadiene/styrene copolymer, a styrene/butadiene/butylene/styrene copolymer, a butadiene polymer, a styrene/butadiene copolymer, and an acrylonitrile/butadiene copolymer.

### Advantageous Effects of Invention

In the present invention, there can be provided a resin composition for a semiconductor device of a wafer level chip size package type, which exhibits excellent high-frequency properties, and even when applying the composition to a semiconductor substrate using a spin coater, can form a coating film which has a thickness that has less unevenness, and is unlikely to cause warpage of the semiconductor substrate, a semiconductor device using the same, and a method for producing a semiconductor device.

### BRIEF DESCRIPTION OF THE DRAWING

FIG. 1 is a schematic cross-sectional view schematically showing the construction of a part of a WL-CSP type semiconductor device.

### DETAILED DESCRIPTION

Hereinbelow, embodiments of the resin composition of the present disclosure for a semiconductor device of a wafer level chip size package type, a semiconductor device using the same, and a method for producing a semiconductor device will be described. The following embodiments are examples for specifically describing the technical idea of the present invention, and the present invention is not limited to the below-described resin composition, semiconductor device using the same, and method for producing a semiconductor device.

The resin composition according to the first embodiment of the present invention comprises a specific modified polyphenylene ether (frequently referred to as “component (A)”) and (B) an elastomer having a butadiene skeleton (frequently referred to as “component (B)”). The resin composition contains the modified polyphenylene ether as component (A), and therefore a coating film which is formed from a cured product obtained by curing the resin composition and which constitutes an interlayer dielectric film preferably has a relative permittivity (ε) of 3.0 or less, more preferably 2.9 or less, further preferably 2.8 or less, especially preferably 2.7 or less. The coating film which is formed from a cured product obtained by curing the resin composition and which constitutes an interlayer dielectric film may have a relative permittivity (ε) of 1.0 or more, preferably 1.5 or more. Further, the coating film which is formed from the resin composition and which constitutes an interlayer dielectric film preferably has a dielectric loss tangent (tanδ) of 0.015 or less, more preferably 0.014 or less, further preferably 0.013 or less. The coating film which is formed from the resin composition and which constitutes an interlayer dielectric film preferably has a dielectric loss tangent (tanδ) of 0.001 or more. When a coating film which is formed from the resin composition and which constitutes an interlayer dielectric film for a WL-CSP type semiconductor device has a relative permittivity of 3.0 or less and a dielectric loss tangent (tanδ) of 0.015 or less, the coating film has a low permittivity and a low dielectric loss tangent and exhibits excellent electrical properties when used in a high frequency region. For example, there can be obtained a coating film which exhibits excellent electrical properties when a semiconductor device having such a coating film is used in a high frequency region for, for example, fifth-generation mobile communications system “5G”, which is expected to be further increased in the capacity and transmission speed.

The resin composition contains the component (A) and component (B), and therefore the resin composition applied to a semiconductor substrate uniformly shrinks when being cured, so that the semiconductor substrate is unlikely to suffer warpage. Thus, the resin composition containing the component (A) and component (B) is suitable for forming an interlayer dielectric film for a WL-CSP type semiconductor device.

The resin composition preferably further comprises (C) a solvent (frequently referred to as “component (C)”) if necessary, in addition to the component (A) and component (B). The resin composition containing the component (A) and component (B) as well as the component (C) has excellent thixotropic properties. With respect to the resin composition containing the component (A) and component (B) as well as the component (C), for example, when the resin composition is applied to a semiconductor substrate using a spin coater, a coating film having a substantially uniform thickness that has less unevenness can be formed.

The resin composition containing the components (A), (B), and (C) preferably has a first viscosity in the range of 300 to 4,000 mPa·s, as measured at 25° C. and at 10 rpm using a rotational viscometer. When the first viscosity of the resin composition is in the range of 300 to 4,000 mPa·s, for example, in the case where the resin composition is applied to a semiconductor substrate using a spin coater, a coating film having a substantially uniform thickness that has less unevenness can be formed, so that warpage of the semiconductor substrate caused during curing of the resin composition can be suppressed. The resin composition more preferably has a first viscosity of 400 to 4,000 mPa·s, further preferably 500 to 2,000 mPa·s. In the present specification, a viscosity can be measured using, as the rotational viscometer, for example, a TVE-type viscometer (cone rotor: 1° 34′ x R²⁴; manufactured by Toki Sangyo Co., Ltd.).

The resin composition containing the components (A), (B), and (C) preferably has a second viscosity in the range of 500 to 4,200 mPa·s, as measured at 25° C. and at 1 rpm using a rotational viscometer. When the second viscosity of the resin composition is in the range of 500 to 4,200 mPa·s, for example, in the case where the resin composition is applied to a semiconductor substrate using a spin coater, a coating film having a substantially uniform thickness that has less unevenness can be formed, so that warpage of the semiconductor substrate caused during curing of the resin composition can be suppressed. The resin composition more preferably has a second viscosity in the range of 550 to 4,000 mPa·s, further preferably in the range of 550 to 3,500 mPa·s.

It is preferred that the resin composition containing the components (A), (B), and (C) has a thixotropy index TI in the range of 0.8 to 1.2, in terms of the ratio of the second viscosity to the first viscosity, and thus has thixotropic properties close to those of a Newtonian fluid. The term “Newtonian fluid” means a fluid having properties such that the shear stress of the fluid is proportional to the shear rate. When the thixotropy index TI of the resin composition is in the range of 0.8 to 1.2, in terms of the ratio of the second viscosity to the first viscosity, for example, in the case where the resin composition is applied to a semiconductor substrate using a spin coater, a coating film having a substantially uniform thickness that has less unevenness can be formed, so that warpage of the semiconductor substrate caused during curing of the resin composition can be suppressed. The resin composition may have a thixotropy index in the range of 0.90 to 1.10, in terms of the ratio of the second viscosity to the first viscosity, and may have a thixotropy index in the range of from 1.00 to 1.10.

In the resin composition, the mass ratio of the component (A) and the component (B) is preferably in the range of 10:90 to 80:20, more preferably in the range of 20:80 to 75:25, further preferably in the range of 30:70 to 70:30. When the mass ratio of the component (A) and the component (B) in the resin composition is in the range of 10:90 to 80:20, a cured product which has a low permittivity and a low dielectric loss tangent and which exhibits excellent electrical properties when used in a high frequency region can be obtained using the resin composition. Further, for example, in the case where the resin composition is applied to a semiconductor substrate using a spin coater, a coating film having a substantially uniform thickness that has less unevenness can be formed, so that a cured product which has suppressed warpage of the semiconductor substrate can be obtained.

In the resin composition, the mass ratio of the total of the components (A) and (B) and the component (C) is preferably in the range of 5:95 to 80:20, more preferably in the range of 10:90 to 70:30, further preferably in the range of 12:88 to 40:60, especially preferably in the range of 18:82 to 50:50. When the mass ratio of the total of the components (A) and (B) and the component (C) in the resin composition is in the range of 5:95 to 80:20, for example, in the case where the resin composition is applied to a semiconductor substrate using a spin coater, a coating film having a substantially uniform thickness that has less unevenness can be formed, so that a cured product which has suppressed warpage of the semiconductor substrate can be obtained.

### Component (A): Modified Polyphenylene Ether

The component (A) is preferably a polyphenylene ether resin having at the end thereof a functional group having a carbon-carbon double bond. The modified polyphenylene ether (PPE) resin is frequently referred to as “component (A)” or “modified PPE resin as component (A)”. The functional group having a carbon-carbon double bond can be, for example, a terminal vinyl group, a vinylene group, a vinylidene group, an acryloyl group, or a methacryloyl group. With respect to the component (A), there is no particular limitation as long as it has at the end thereof a functional group having a carbon-carbon double bond and has polyphenylene ether in the skeleton. By virtue of containing the component (A), low dielectric properties can be imparted to the resin composition, and further the resin composition can be improved in heat resistance and coefficient of thermal expansion. The component (A) is preferably a thermosetting resin. Further, the component (A) is especially preferably a polyphenylene ether resin having a vinyl group at the end thereof. By using the polyphenylene ether resin having a vinyl group at the end in the resin composition, low dielectric properties can be achieved

It is preferred that the modified PPE resin as component (A) comprises a PPE resin represented by the following formula (1).

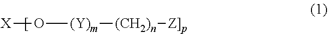

(in the formula (1), X represents a p-valent unsubstituted or substituted aromatic hydrocarbon group,

Y represents an unsubstituted or substituted phenol repeating unit represented by the following formula (2):

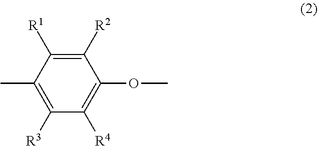

(in the formula (2), each of R¹ to R⁴ independently represents a hydrogen atom, an alkyl group, an alkenyl group, an alkynyl group, or an alkenylcarbonyl group.),

Z is a terminal functional group having a carbon-carbon double bond, and represents a vinyl group, a vinylene group, an (meth)acryloyl group represented by the following formula (3) or a styrene group represented by the following formula (4):

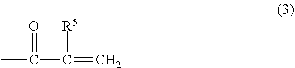

(in the formula (3), R⁵ represents a hydrogen atom or an alkyl group.),

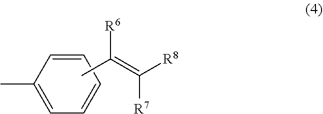

(in the formula (4), each of R⁶ to R⁸ independently represents a hydrogen atom, an alkyl group, an alkenyl group, or an alkynyl group.),
m represents an integer of 1 to 100,
n represents an integer of 0 or 1 to 6, and
p represents an integer of 1 to 4.)

It is preferred that the PPE resin as component (A) comprises at least one member selected from the group consisting of a modified PPE resin represented by the following formula (5) and a modified PPE resin represented by the following formula (6).

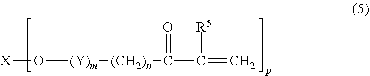

(in the formula (5), R⁵ represents a hydrogen atom or an alkyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents an integer of 0 or 1 to 6, and
p represents an integer of 1 to 4.)

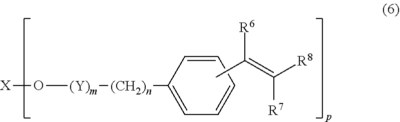

(in the formula (6), each of R⁶ to R⁸ independently represents a hydrogen atom, an alkyl group, an alkenyl group, or an alkynyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents an integer of 0 or 1 to 6, and
p represents an integer of 1 to 4.)

Generally, a x-valent (x represents an integer of 1 or more.) hydrocarbon group indicates a x-valent group obtained by removing x hydrogen atom or atoms from the carbon atom or atoms of a hydrocarbon. X indicates a p-valent unsubstituted or substituted aromatic hydrocarbon group, which is a mono-, di-, tri-, or tetra-valent group obtained by removing 1 to 4 hydrogen atoms from the carbon atom or atoms of an unsubstituted or substituted aromatic hydrocarbon.

The term “alkyl group” means a monovalent saturated hydrocarbon group. In the present invention, the alkyl group is preferably a C₁-C₁₀ alkyl group, more preferably a C₁-C₆ alkyl group, further preferably a C₁-C₄ alkyl group, especially preferably a C₁-C₂ alkyl group. Examples of such alkyl groups include a methyl group, an ethyl group, a propyl group, an isopropyl group, a butyl group, an isobutyl group, a sec-butyl group, a tert-butyl group, a pentyl group, and a hexyl group.

The term “alkenyl group” means a monovalent unsaturated hydrocarbon group having at least one carbon carbon double bond. In the present invention, the alkenyl group is preferably a C₂-C₁₀ alkenyl group, more preferably a C₂-C₆ alkenyl group, further preferably a C₂-C₄ alkenyl group. Examples of such alkenyl groups include an ethenyl group (vinyl group), a 1-propenyl group, a 2-propenyl group, a 1-butenyl group, a 2-butenyl group, an isobutenyl group, a 1-pentenyl group, and a 1-hexenyl group. The group —CR¹═CR²R³ in the formula (1) above is also an alkenyl group.

The term “alkynyl group” means a monovalent unsaturated hydrocarbon group having at least one carbon-carbon triple bond. In the present invention, the alkynyl group is preferably a C₂-C₁₀ alkynyl group, more preferably a C₂-C₆ alkynyl group, further preferably a C₂-C₄ alkynyl group. Examples of such alkynyl groups include an ethynyl group, a 1-propynyl group, a 2-propynyl group, a butynyl group, an isobutynyl group, a pentynyl group, and a hexynyl group.

The term “alkenylcarbonyl group” means a carbonyl group substituted with the above-mentioned alkenyl group, and examples of such groups include an acryloyl group and a methacryloyl group.

With respect to the component (A), in the formula (1), (5), or (6), the portion represented by —(Y)ₘ— corresponds to the principal chain of the PPE resin. It is preferred that, in unsubstituted or substituted phenol repeating unit Y, R¹ and R³ represent a hydrogen atom and R² and R⁴ represent a methyl group. In the formula (1), one end of the portion represented by —(Y)ₘ— is bonded to an aromatic hydrocarbon group X through an oxygen atom, and another end is bonded to an end group (Z) through n methylene group or groups. In the formula (5), one end of the portion represented by —(Y)ₘ— is bonded to an aromatic hydrocarbon group X through an oxygen atom, and another end is bonded to a methacryloyl group through n methylene group or groups. In the formula (6), one end of the portion represented by —(Y)ₘ— is bonded to an aromatic hydrocarbon group X through an oxygen atom, and another end is bonded to a styrene group through n methylene group or groups, and the alkenyl group —CR⁶═CR⁷R⁸ may be present at any of the ortho-position, the meta-position, and the para-position with respect to the methylene group. In one aspect, n in the formula (1), (5), or (6) is an integer of 0 or 1 to 4. In another aspect, n in the formula (1), (5), or (6) is 0, 1, or 2. In another aspect, n in the formula (1) is 0 or 1. In still another aspect, all of R⁶ to R⁸ in the formula (6) are a hydrogen atom.

Further, m in the formula (1), (5), or (6), which is the number of repeating units Y, is preferably 1 to 80, more preferably 1 to 30, further preferably 1 to 5.

In the component (A), p portions represented by —(Y)ₘ— are bonded to the aromatic hydrocarbon group X in the formula (1), (5), or (6) through an oxygen atom, respectively. p is preferably 2 or 3. p is more preferably 2. X preferably has a structure represented by the following formula:

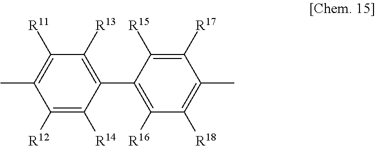

(in the formula, each of R¹¹ to R¹⁸ independently represents a hydrogen atom or a C₁-C₆ alkyl group.).

X more preferably has a structure represented by the following formula:

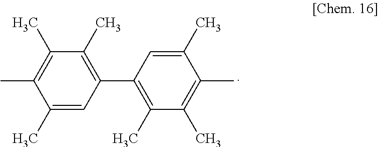

With respect to the end of the principal chain of the modified polyphenylene ether resin as component (A), the polyphenylene ether resin may be a polyphenylene ether resin having 1.5 to 5 functional groups represented by the formula (1), (5), or (6) in average per molecule at the end of the principal chain. The terminal functional group is preferably a methacryloyl group and/or an acryloyl group from the viewpoint of imparting further excellent heat resistance to a cured product of the resin composition, and is more preferably a methacryloyl group from the viewpoint of achieving further excellent resin fluidity during heat forming.

Further, from the viewpoint of easy application of the resin composition to a semiconductor substrate, for example, using a spin coater, electrical properties of a coating film formed from the resin composition, such as low dielectric properties and low dielectric loss tangent, compatibility with the other components contained in the resin composition, and the like, the component (A) preferably has a number average molecular weight of 500 or more and 5,000 or less. The number average molecular weight of the component (A) is more preferably 750 or more and 3,000 or less, further preferably 1,000 or more and 2,500 or less. When the number average molecular weight (Mn) of the component (A) is too small, it is likely that a cured product obtained by curing the resin composition is reduced in toughness. On the other hand, when the number average molecular weight (Mn) of the component (A) is too large, it is likely that the compatibility of the component (A) with the solvent as component (C) is reduced, making it difficult to apply the resin composition to a semiconductor substrate, for example, using a spin coater. The number average molecular weight (Mn) of the component (A) or component (B) can be determined from, for example, a polystyrene converted value measured by gel permeation chromatography (GPC). In the present specification, the number average molecular weight (Mn) can be measured, for example, using high performance liquid chromatography (for example, LC-2OAD, manufactured by Shimadzu Corporation) and using a column (for example, KF-802, manufactured by Showa Denko K.K.) and a tetrahydrofuran (THF) solution as a solvent.

The amount of the component (A) contained in the resin composition is preferably 5.0 to 40.0% by mass, more preferably 7.0 to 35.0% by mass, further preferably 8.0 to 30.0% by mass, especially preferably 9.0 to 25.0% by mass, based on the total mass of the components (A), (B), and (C) (100% by mass). When the amount of the component (A) contained in the resin composition is 5.0 to 40.0% by mass, based on the total mass of the components (A), (B), and (C) (100% by mass), a cured product having a low permittivity and a low dielectric loss tangent can be obtained from the resin composition, and the cured product exhibits excellent electrical properties suitable for the use in a high frequency region.

With respect to the component (A), a commercially available product can be used. As a commercially available product of the component (A), which is a modified PPE resin represented by the formula (5), for example, a modified PPE resin having 1.5 to 5 terminal methacryloyl groups represented by the formula (3) per molecule, NORYL SA9000 (manufactured by SABIC Innovative Plastics Japan LLC.) can be used. As a commercially available product of the component (A), which is a modified PPE resin represented by the formula (6), for example, OPE 2St 1200, or OPE 2st 2200 (manufactured by Mitsubishi Gas Chemical Company, Inc.) can be used. The component (A) can be prepared by a known method. For example, the component (A) can be prepared by a method which comprises subjecting an appropriate p-valent phenol (such as 2,2′, 3,3′,5,5′-hexamethylbiphenyl-4,4′-diol) having a structure represented by the formula: X—(OH)ₚ (in the formula, X and p are as defined above.) and an appropriate monovalent phenol (such as 2,6-dimethylphenol) having a structure represented by the following formula:

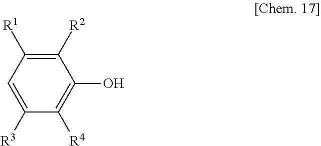

(in the formula, R¹ to R⁴ are as defined above.), to oxidative copolymerization by a known method to prepare a polyphenylene ether resin having a hydroxyl group at the end thereof, and modifying the obtained resin through a reaction with an appropriate modifier, for example, chloromethylstyrene.

### Component (B): Elastomer Having a Butadiene Skeleton

The elastomer having a butadiene skeleton as component (B) needs to have at least a butadiene skeleton in the molecule thereof, and may be a partially hydrogenated elastomer. As an example of the elastomer having a butadiene skeleton, there can be mentioned a block copolymer comprising a styrene or similar structure block as at least one end block and a conjugated diene elastomer block as at least one intermediate block. It is preferred that the elastomer having a butadiene skeleton as component (B) comprises at least one member selected from the group consisting of a styrene/butadiene/styrene copolymer (SBS), a styrene/butadiene/butylene/styrene copolymer (SBBS), a butadiene polymer (BR), a styrene/butadiene copolymer (SBR), and an acrylonitrile/butadiene copolymer (NBR). The elastomer having a butadiene skeleton may be partially modified, and may be, for example, a carboxylated nitrile butadiene rubber (NBR) which has an end modified with a carboxyl.

The resin composition containing the component (A) and the elastomer having a butadiene skeleton as component (B) shrinks more uniformly when being cured, so that warpage of the semiconductor substrate can be suppressed. Further, when a solvent as component (C) is used in the resin composition, the components (A) and (B) are easily dissolved in the solvent as component (C), so that the resultant resin composition exhibits more excellent thixotropic properties, and, for example, in the case where the resin composition is applied to a semiconductor substrate using a spin coater, a coating film having a substantially uniform thickness that has even less unevenness can be formed. Particularly, from the viewpoint of achieving excellent electrical properties when used in a high frequency region, preferred is a styrene elastomer having a double bond, and preferred examples include a styrene elastomer comprising a styrene/butadiene/styrene copolymer (SBS), a styrene/butadiene/butylene/styrene copolymer (SBBS), or a styrene/butadiene copolymer. The component (B) may be a reactive elastomer having incorporated a functional group, such as an amine. By using a reactive elastomer having a functional group incorporated, the resin composition can be further improved in adhesive strength (peel strength). The component (B) preferably has a weight average molecular weight of 20,000 to 200,000, more preferably 30,000 to 150,000. The weight average molecular weight is a value as determined by a gel permeation chromatography method (GPC) using a conversion calibration curve obtained from the standard polystyrene.

It is preferred that the elastomer having a butadiene skeleton as component (B) comprises at least one member selected from the group consisting of a styrene/butadiene/styrene block copolymer represented by the following formula (7) and an acrylonitrile/butadiene copolymer represented by the following formula (8).

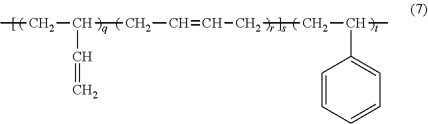

(in the formula (7), q and r represent an integer of 0 or 1, with the proviso that at least one of q and r is not 0, s represents an integer of 1 to 1,200, and t represents an integer of 1 to 1,000.).

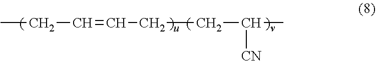

(in the formula (8), u represents an integer of 1 to 1,200, and v represents an integer of 1 to 1,000.).

The styrene/butadiene/styrene block copolymer (SBS) represented by the formula (7), which is the component (B), is a non-hydrogenated block copolymer. By virtue of containing the styrene/butadiene/styrene block copolymer as the component (B), the resin composition is improved in the flexibility or solubility in a solvent, so that the resin composition can be advantageously applied to a semiconductor substrate using a spin coater. Further, also when containing a styrene/butadiene/butylene/styrene copolymer (SBBS) which is a partially hydrogenated elastomer, the resin composition can be similarly advantageously applied to a semiconductor substrate. On the other hand, it is preferred that the resin composition or the component (B) does not contain an elastomer having no double bond. As an example of the elastomer having no double bond, there can be mentioned a styrene/ethylene/butylene/styrene block copolymer (SEBS) obtained by completely hydrogenating a styrene/butadiene/styrene block copolymer. It is likely that the SEBS is reduced in compatibility with the solvent as component (C) and thus the resin composition cannot achieve a desired viscosity, making it difficult to apply the resin composition to a semiconductor substrate using, for example, a spin coater. The mechanism of the phenomenon has not yet been elucidated, but it is presumed that the styrene/butadiene/styrene block copolymer (SBS) and styrene/butadiene/butylene/styrene copolymer (SBBS) still have a double bond of butadiene, and therefore are improved in the solubility in the solvent, as compared to the styrene/ethylene/butylene/styrene block copolymer (SEBS). The present invention is not restricted by such assumption.

In the formula (7), s may represent an integer of 1 to 1,200, and may represent an integer of 150 to 900. In the formula (7), t may represent an integer of 1 to 1,000, and may represent an integer of 50 to 700.

Further, when the component (B) comprises an acrylonitrile/butadiene copolymer (NBR) represented by the formula (8) and a solvent as component (C) is used in the resin composition, the NBR is easily dissolved in the solvent as component (C) and the resin composition exhibits more excellent thixotropic properties, and, for example, in the case where the resin composition is applied to a semiconductor substrate using a spin coater, a coating film having a substantially uniform thickness that has less unevenness can be formed.

The amount of the styrene contained in the component (B) in the resin composition is preferably in the range of 10 to 70% by mass, more preferably in the range of 15 to 60% by mass, further preferably in the range of 20 to 55% by mass, based on the mass of the resin composition (100% by mass). When the amount of the styrene contained in the component (B) in the resin composition is in the range of 10 to 70% by mass, based on the mass of the resin composition (100% by mass), the resin composition being cured exhibits excellent stretchability, and, for example, in the case where the resin composition is applied to a semiconductor substrate, warpage of the semiconductor substrate during curing of the resin composition can be suppressed.

The amount of the styrene contained in the component (B) in the resin composition can be measured by nuclear magnetic resonance (NMR). Specifically, tetrachloroethane is used as a solvent, and the amount of the styrene can be calculated from the values obtained by determining an integral value of a peak in the range of 5.5 ppm to 6.5 ppm, which is ascribed to styrene, and an integral value of peaks in the other range.

In the component (B), the styrene/butadiene ratio (% by mass) may be 15/85 or more, and may be 20/80 or more, and is preferably 70/30 or less, and may be 60/40 or less, and may be 55/45 or less.

Taking into consideration the uniformity of the thickness of a coating film obtained by applying the resin composition to a semiconductor substrate, for example, using a spin coater, suppression of warpage of the semiconductor substrate caused during curing of the resin composition, and compatibility with the solvent as component (C), the component (B) preferably has a number average molecular weight (Mn) of 40,000 or more and 600,000 or less, more preferably 50,000 or more and 150,000 or less, further preferably 60,000 or more and 120,000 or less. The number average molecular weight (Mn) of the component (B) can be determined by the same method as mentioned above, for example, from a polystyrene converted value obtained by measurement of gel permeation chromatography (GPC).

In the resin composition, it is preferred that the component (A) comprises a modified polyphenylene ether resin represented by the formula (6) and the component (B) comprises a styrene/butadiene/styrene copolymer (SBS). In the resin composition, the component (A) contains a modified PPE resin represented by the formula (6) and the component (B) contains an SBS, and therefore the resin composition applied to a semiconductor substrate uniformly shrinks when being cured, so that the semiconductor substrate is unlikely to suffer warpage. Thus, the resin composition is suitable for forming an interlayer dielectric film for a WL-CSP type semiconductor device.

The amount of the component (B) contained in the resin composition is preferably 5.0 to 40.0% by mass, more preferably 7.0 to 35.0% by mass, further preferably 8.0 to 30.0% by mass, especially preferably 9.0 to 25.0% by mass, based on the total mass of the components (A), (B), and (C) (100% by mass). When the amount of the component (B) contained in the resin composition is 5.0 to 40.0% by mass, based on the total mass of the components (A), (B), and (C) (100% by mass), a cured product having a low permittivity and a low dielectric loss tangent can be obtained from the resin composition, and the cured product exhibits excellent electrical properties suitable for the use in a high frequency region. Further, when the amount of the component (B) contained in the resin composition is 5.0 to 40.0% by mass, based on the total mass of the components (A), (B), and (C) (100% by mass), for example, in the case where the resin composition is applied to a semiconductor substrate using a spin coater, a coating film having a substantially uniform thickness that has less unevenness can be formed, so that a cured product which has suppressed warpage of the semiconductor substrate can be obtained.

With respect to the component (B), a commercially available product can be used. Examples of commercially available products of the component (B) include trade name “TR2827”, “TR2000”, “TR2003”, “TR2250”, manufactured by JSR Corporation; trade name “P1083”, “P1500”, “P5051”, “MP10”, manufactured by Asahi Kasei Chemicals Corporation; and trade name “Nipol (trademark) 1072”, manufactured by Zeon Corporation.

### Component (C): Solvent

It is preferred that the resin composition comprises a solvent as the component (C). The solvent as component (C) is preferably an organic solvent. With respect to the organic solvent, preferred is an organic solvent such that the component (A) and component (B) can be easily dissolved or dispersed in the solvent, and, for example, when the resultant resin composition is applied to a semiconductor substrate using a spin coater, a coating film having a substantially uniform thickness that has less unevenness can be formed, and the solvent is unlikely to remain in the coating film, a lowering of the dielectric properties can be suppressed. The organic solvent preferably contains at least one member selected from the group consisting of an aromatic solvent and a ketone solvent. The solvent as component (C) is preferably at least one member selected from the group consisting of toluene, xylene, acetone, methyl ethyl ketone, methyl isobutyl ketone, acetophenone, cyclohexanone, cyclohexane, dimethyl carbonate, methylcyclohexanone, and γ-butyrolactone. The solvents as component (C) may be used individually or in combination with 2 or more. With respect to the solvent as component (C), toluene or cyclohexanone may be used, and, of these, from the viewpoint of the toxicity, cyclohexanone is preferably used. The resin composition can be used in the form of a varnish that is obtained by dissolving or dispersing the component (A) and component (B) in the solvent as component (C). A varnish comprising the resin composition containing the components (A), (B), and (C) preferably has the above-mentioned first viscosity and second viscosity. Further, the varnish comprising the resin composition containing the components (A), (B), and (C) preferably has the above-mentioned thixotropy index TI.

The amount of the component (C) contained in the resin composition is preferably in the range of 20 to 90% by mass, based on the total mass of the components (A), (B), and (C) (100% by mass), and may be in the range of 30 to 86% by mass, and may be in the range of 40 to 84% by mass, and may be in the range of 50 to 82% by mass. When the amount of the component (C) contained is in the range of from 20 to 90% by mass, based on the total mass of the components (A), (B), and (C) (100% by mass), the component (A) and component (B) can be easily dissolved or dispersed in the component (C), and, for example, in the case where the resin composition is applied to a semiconductor substrate using a spin coater, a coating film having a substantially uniform thickness that has less unevenness can be formed, and the solvent is unlikely to remain in the coating film, so that a lowering of the dielectric properties can be suppressed.

With respect to the component (C), a commercially available product can be used. As a commercially available product of the component (C), for example, toluene (toluene concentration: 100% by mass; manufactured by Daishin Chemical Co., Ltd.), Anone (cyclohexanone) (cyclohexanone concentration: 90 to 100% by mass; manufactured by Daishin Chemical Co., Ltd.), or the like can be used.

The resin composition needs to contain at least the component (A) and component (B), and the resin composition may contain the component (C), and may contain a component or components other than the components (A), (B), and (C), and may not contain a component other than the components (A), (B), and (C). The resin composition may comprise only the components (A), (B), and (C).

The resin composition may contain a coupling agent for improving the adhesion to a semiconductor substrate. Further, the resin composition may contain an organic peroxide for improving the reactivity. The resin composition may contain at least one additive selected from the group consisting of an organic peroxide, a coupling agent, an ion trapping agent, a leveling agent, an antioxidant, a viscosity modifier, and a flame retardant. The coupling agent is a compound having two or more different functional groups per molecule, in which one is a functional group that undergoes chemical bonding to an inorganic material, and another one is a functional group that undergoes chemical bonding to an organic material. As examples of the coupling agents, there can be mentioned at least one member selected from the group consisting of a silane coupling agent, an aluminum coupling agent, and a titanium coupling agent, and a silane coupling agent may be used. The coupling agents may be used individually or in combination with 2 or more. Examples of functional groups of the silane coupling agent include an alkoxy group, a vinyl group, an epoxy group, a styryl group, a methacryl group, an acryl group, an amino group, an isocyanurate group, an ureido group, a mercapto group, a sulfide group, and an isocyanate group.

Taking the reactivity of the component (A) and component (B) into consideration, the resin composition may contain an organic peroxide for initiating a radical polymerization reaction. As the organic peroxide, a peroxycarbonate or the like can be used. As the peroxycarbonate, PERBUTYL (trademark) Z, manufactured by NOF Corporation, can be used.

The amount of the additive contained in the resin composition may be 10.0% by mass or less, based on the mass of the resin composition (100% by mass), and may be 8.0% by mass or less, and may be 5.0% by mass or less. The amount of the additive contained in the resin composition may be 0.10% by mass or more, and may be 0.20% by mass or more, and may be 0.30% by mass or more, and may be 0.50% by mass or more. With respect to the additive, a commercially available product may be used, and, when the additive is a silane coupling agent, for example, 3-methacryloxypropyltrimethoxysilane KBM 503, vinyltrimethoxysilane KBM 1003 (Shin-Etsu Silicone, manufactured by Shin-Etsu Chemical Co., Ltd.), or Coatsil MP200 Silane (manufactured by Momentive Performance Materials Japan LLC) can be used.

The present resin composition is a resin composition for a semiconductor device of a non-photosensitive wafer level chip size package type. It is preferred that the present resin composition does not contain an inorganic filler, such as silica. When an interlayer dielectric film is formed using a thermosetting insulating resin, the interlayer dielectric film is irradiated with a laser for perforation processing in the subsequent step to form a via hole for wiring. In this processing, when the interlayer dielectric film contains an inorganic filler, such as silica, it is likely that the laser treatment cannot well process the silica portion, making it difficult to advantageously achieve the subsequent copper plating for a via hole. Therefore, it is preferred that the resin composition does not contain an inorganic filler, such as silica. Here, the resin composition which does not contain an inorganic filler, such as silica, means that an inorganic filler is intentionally not added to the resin composition, and the resin composition may contain an inorganic material in an amount in the range of 0.0001 to 0.01% by mass, based on the mass of the resin composition (100% by mass), and may contain an inorganic material in an amount of 0% by mass or may contain no inorganic material.

### Method for Producing the Resin Composition

The resin composition can be produced by mixing the component (A) and component (B) and optionally the component (C). The resin composition may be produced by mixing the component (A) and component (B) and optionally the component (C) and optionally an additive. Addition of a filler, such as silicon dioxide or aluminum oxide, may cause the resin composition to have poor application properties, and therefore is not preferred. It is preferred that the resin composition does not contain a silicon dioxide or aluminum oxide powder. With respect to the method for producing the resin composition, there is no particular limitation. The resin composition can be produced by mixing raw materials for the components by means of a mixing machine, such as a mortar machine, a pot mill, a three-roll mill, a hybrid mixer, a rotary mixer, or a twin-screw mixer. The components of the resin composition may be mixed in such a way that all the components are mixed at the same time, or in such a way that part of the components are first mixed with each other and then the remaining components are mixed into the mixture. Further, the above apparatus appropriately selected may be used in combination in the production of the resin composition.

The cured product obtained by curing the resin composition preferably has a relative permittivity (ε) of 3.0 or less, more preferably 2.8 or less, further preferably 2.7 or less. The cured product preferably has a dielectric loss tangent (tanδ) of 0.015 or less, more preferably 0.014 or less, further preferably 0.013 or less. The cured product having a low permittivity and a low dielectric loss tangent exhibits excellent electrical properties when used in a high frequency region, and therefore can be used in an electronic part, a semiconductor device, and the like which are used in a high frequency region. Further, when the resin composition is applied to a semiconductor substrate using, for example, a spin coater, the composition is satisfactorily cured, so that a cured product in a thin film form can be obtained in which the cured product has a substantially uniform thickness and exhibits excellent electrical properties when a semiconductor device having such a cured product is used in a high frequency region for, for example, fifth-generation mobile communications system “5G”, which is expected to be further increased in the capacity and transmission speed. Therefore, the resin composition can be advantageously used in a semiconductor device which comprises a semiconductor substrate, an electrode disposed on the semiconductor substrate, a wiring connected to the electrode, an external terminal electrically connected to the electrode through the wiring, and an interlayer dielectric film, as a material for forming the interlayer dielectric film for encapsulating the side of the semiconductor substrate on which the electrode and the wiring are disposed. The interlayer dielectric film is disposed so as to be in contact with the wiring. In the present specification, the “redistribution layer” includes a wiring and an interlayer dielectric film. In general documents, the “wiring” may be described as “redistribution layer”, and the “interlayer dielectric film” may be described as “encapsulation resin layer”. Further, the resin composition can be advantageously used in the semiconductor device as a material for forming the interlayer dielectric films for encapsulating the semiconductor substrate side of the wiring and the side of the wiring opposite to the semiconductor substrate. The redistribution layer can have a thickness of about 5 to 30 μm. The thickness of the redistribution layer may be 5 μm or more, and may be 10 μm or more. Further, the thickness of the redistribution layer may be 30 μm or less, and may be 20 μm or less.

The resin composition can be advantageously used as an encapsulation resin for a WL-CSP type semiconductor device.

Next, a WL-CSP type semiconductor device using the resin composition is described below. The WL-CSP type semiconductor device comprises a semiconductor substrate, an electrode disposed on the semiconductor substrate, a wiring connected to the electrode, an external terminal electrically connected to the electrode through the wiring, and an interlayer dielectric film for encapsulating the side of the semiconductor substrate on which the electrode and the wiring are disposed, in which the interlayer dielectric film is formed using the above-mentioned resin composition containing the components (A), (B), and (C). The interlayer dielectric film is disposed so as to be in contact with the wiring. It is preferred that the WL-CSP type semiconductor device having the interlayer dielectric film comprises at least two layers of a first interlayer dielectric film (frequently referred to as “dielectric film”) for encapsulating the semiconductor substrate side of the wiring and a second interlayer dielectric film for encapsulating the side of the wiring opposite to the semiconductor substrate. Both the two layers of the first interlayer dielectric film (dielectric film) and second interlayer dielectric film are disposed so as to be in contact with the wiring, and function as an interlayer dielectric film for the wiring.

### Semiconductor Device

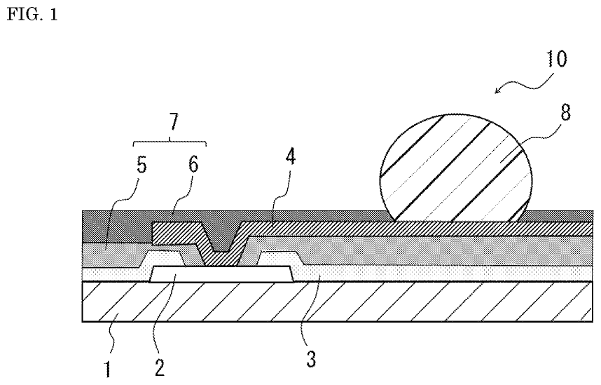

The WL-CSP type semiconductor device is described with reference to a drawing. FIG. 1 is a schematic cross-sectional view schematically showing the construction of a WL-CSP type semiconductor device. The WL-CSP type semiconductor device is not limited to the example shown in FIG. 1.

A WL-CSP type semiconductor device 10 comprises, on a semiconductor substrate 1, an electrode 2, a wiring 4 connected to the electrode 2, and an external connection terminal 8 electrically connected to the wiring 4, such as an electrically conductive ball. A protective layer 3 composed of an oxide film or the like may be formed between the wiring 4 and the semiconductor substrate 1. The WL-CSP type semiconductor device 10 has interlayer dielectric films 5, 6 for encapsulating the side of the semiconductor substrate 1 on which the electrode 2 and wiring 4 are disposed. The interlayer dielectric films 5, 6 are disposed so as to be in contact with the wiring 4. The semiconductor device may have at least two layers of the interlayer dielectric films 5, 6, in which the film for encapsulating the semiconductor substrate 1 side of the wiring 4 corresponds to the first interlayer dielectric film (dielectric film) 5, and the film for encapsulating the side of the wiring 4 opposite to the semiconductor substrate 1 corresponds to the second interlayer dielectric film 6. Both the two layers of the first interlayer dielectric film (dielectric layer) 5 and the second interlayer dielectric film 6 are disposed so as to be in contact with the wiring 4. By using the same resin composition in the first interlayer dielectric film 5 and the second interlayer dielectric film 6, both lower dielectric properties and excellent electrical properties when used in a high frequency region can be achieved. The wiring 4, the first interlayer dielectric film (dielectric film) 5, and the second interlayer dielectric film 6 constitute a redistribution layer 7.

### Method for Producing a Semiconductor Device

Next, a method for producing a WL-CSP type semiconductor device is described below. Hereinafter, the semiconductor device means a WL-CSP type semiconductor device unless otherwise specified.

With respect to the semiconductor substrate, a semiconductor substrate composed of a material, such as silicon, SiGe, or SOI, or the like, can be used. With respect to the electrode, a film of an electrode material is formed on the substantially entire surface of the semiconductor substrate by, for example, a vacuum deposition method or a sputtering method, and then patterned by, for example, a photolithography method, forming a plurality of electrodes on the semiconductor substrate at predetermined positions.

The electrodes are formed on the surface of the semiconductor substrate, and then a film of silicon nitride (SiN) is formed on the entire surface of the semiconductor substrate by, for example, a vapor deposition method, and further an oxide film (passive film) is formed on the surface of the silicon nitride, forming a protective layer. With respect to the thickness of the semiconductor substrate, electrode, and protective layer, there is no particular limitation.

Then, the resin composition is applied dropwise onto the semiconductor substrate, and the semiconductor substrate is spun on the vertical axis using a spin coater to apply the resin composition in a liquid state to the semiconductor substrate, and the resin composition in a liquid state is cured to form an interlayer dielectric film. Specifically, the resin composition is applied dropwise onto the electrode and the protective layer on the semiconductor substrate, and the semiconductor substrate is spun on the vertical axis using a spin coater to apply the resin composition in a liquid state onto the electrode and the protective layer on the semiconductor substrate, and the resin composition in a liquid state is cured to form a first interlayer dielectric film (dielectric film).

In the application of the resin composition for forming the interlayer dielectric film, the rotational speed of the spin coater is preferably 1,000 rpm to 3,000 rpm, and the time of rotation is preferably 5 seconds to 30 seconds. When the rotational speed of the spin coater and the time of rotation are in the above-mentioned respective ranges, the resin composition can be applied onto the semiconductor substrate so as to have a substantially uniform thickness, and, after cured, then interlayer dielectric film having a substantially uniform thickness as desired can be formed, so that warpage of the semiconductor substrate caused during curing of the resin composition can be suppressed.

The interlayer dielectric film can be formed using the above-mentioned resin composition containing the component (A) and component (B) and optionally the component (C). By virtue of using the above-mentioned resin composition, when the resin composition is applied to the semiconductor substrate using a spin coater, a coating film having a substantially uniform thickness that has less unevenness can be formed, so that the first interlayer dielectric film (dielectric film) which has suppressed warpage of the semiconductor substrate during curing of the resin composition can be formed.

The above-mentioned resin composition containing the component (A) and component (B) and optionally the component (C) can be used for forming the interlayer dielectric film, and the interlayer dielectric film may be either a first interlayer dielectric film (dielectric film) or a second interlayer dielectric film. The above-mentioned component (A) preferably comprises a modified PPE resin represented by the formula (1), and the component (A) preferably comprises at least one member selected from the group consisting of a modified PPE resin represented by the formula (5) and a modified PPE resin represented by the formula (6). The above-mentioned component (B) preferably comprises at least one member selected from the group consisting of an SBS represented by the formula (7) and an NBR represented by the formula (8).

It is preferred that the spin coater has a rotational speed of 1,000 rpm to 3,000 rpm and the time of rotation is 5 to 30 seconds.

In the application of the above-mentioned resin composition to a semiconductor substrate using a spin coater, the resin composition preferably has a first viscosity of 300 mPa·s to 4,000 mPa·s, more preferably 400 mPa·s to 4,000 mPa·s, further preferably 500 mPa·s to 2,000 mPa·s, as measured at 25° C. and at 10 rpm using a rotational viscometer. In the application of the above-mentioned resin composition to the semiconductor substrate using the spin coater, when the first viscosity of the resin composition is in the above range, a coating film having a substantially uniform thickness that has less unevenness can be formed, so that warpage of the semiconductor substrate caused during curing of the resin composition can be suppressed.

In the application of the above-mentioned resin composition to a semiconductor substrate using a spin coater, the resin composition preferably has a second viscosity in the range of from 500 mPa·s to 4,200 mPa·s, more preferably in the range of from 550 mPa·s to 4,200 mPa·s, further preferably in the range of from 550 mPa·s to 4,000 mPa·s, still further preferably in the range of from 550 mPa·s to 3,500 mPa·s, as measured at 25° C. and at 1 rpm using a rotational viscometer. In the application of the above-mentioned resin composition to the semiconductor substrate using the spin coater, when the second viscosity of the resin composition is in the above range, a coating film having a substantially uniform thickness that has less unevenness can be formed, so that warpage of the semiconductor substrate caused during curing of the resin composition can be suppressed.

In the application of the above-mentioned resin composition to a semiconductor substrate using a spin coater, the resin composition preferably has a thixotropy index TI in the range of from 0.8 to 1.2, in terms of the ratio of the second viscosity to the first viscosity, and the thixotropy index TI of the resin composition may be in the range of from 0.9 to 1.1, and may be in the range of from 1.0 to 1.1. In the application of the above-mentioned resin composition to the semiconductor substrate using the spin coater, when the ratio of the second viscosity to the first viscosity of the resin composition is in the above range, a coating film having a substantially uniform thickness that has less unevenness can be formed, so that warpage of the semiconductor substrate caused during curing of the resin composition can be suppressed.

With respect to the interlayer dielectric film, the first interlayer dielectric film (dielectric film), and the second interlayer dielectric film, each film preferably has a thickness in the range of 3 μm or more and 20 μm or less, and may have a thickness in the range of 4 μm or more and 18 μm or less, and may have a thickness in the range of 5 μm or more and 17 μm or less. With respect to the interlayer dielectric film, the first interlayer dielectric film (dielectric film), and the second interlayer dielectric film, when the thickness of each layer is in the range of 3 μm or more and 20 μm or less, even a semiconductor device having a plurality of the films stacked can meet the requirements of reduction of size and thickness.

In the method for producing a semiconductor device, the resin composition is applied and then dried, and cured, and then subjected to laser direct patterning using, for example, a laser direct patterning apparatus (manufactured by Mitsubishi Electric Corporation), forming a first interlayer dielectric film (dielectric film) having opened the surface portion of the electrode.

Then, on the substantially entire surface of the semiconductor substrate having formed thereon the electrode, protective layer, and first interlayer dielectric film (dielectric film), a seed layer for forming a wiring is formed by a vapor deposition method, a sputtering method, a chemical vapor deposition (CVD) method, an electroless plating method, or the like. The seed layer contains copper, and may be a seed layer that contains copper oxide, an alloy of copper and chromium, copper, tantalum, cobalt, titanium, or an alloy thereof. The seed layer may have a stacked structure in which a plurality of layers are stacked on one another. On the seed layer, a resist with a predetermined pattern is formed by, for example, a photolithography method, and, using the resultant resist film as a mask, a wiring with the predetermined pattern is formed by electroplating or electroless plating. The wiring is formed and then the resist film is removed, and the seed layer remaining in the region in which the wiring is not formed is removed by etching or the like. With respect to the thickness of the wiring, there is no particular limitation, but the thickness of the wiring may be 0.1 μm or more, and may be 15 μm or less, and may be 12 μm or less, and may be 10 μm or less.

Then, the resin composition is applied onto the wiring using a spin coater so that the surface height of the applied composition becomes substantially uniform, forming a second interlayer dielectric film. In the formation of the second interlayer dielectric film, like the formation of the first interlayer dielectric film, the above-mentioned resin composition containing the components (A), (B), and (C) can be used, and can be applied onto the semiconductor substrate, specifically, onto the wiring using a spin coater having the same rotational speed and time of rotation as those for the first interlayer dielectric film. The resin composition is applied and then dried, and cured, and then subjected to laser direct patterning using, for example, a laser direct patterning apparatus (manufactured by Mitsubishi Electric Corporation), forming a second interlayer dielectric film having opened the surface portion of the wiring corresponding to the portion on which the below-mentioned external terminal is disposed. With respect to the second interlayer dielectric film, the surface portion of the electrode may be opened by exposure and development.

The forming a first interlayer dielectric film (dielectric film), forming a wiring, and forming a second interlayer dielectric film are collectively referred to also as “forming a redistribution layer”.

Then, an external terminal, such as a solder ball, is formed in the opening portion of the redistribution layer by a solder ball mounting method, a solder plating method, a soldering paste method, a soldering paste dispensing method, a solder vapor deposition method, or the like, forming a WL-CSP type semiconductor device. In the thus formed WL-CSP type semiconductor device, the first interlayer dielectric film and second interlayer dielectric film are formed using the above-mentioned resin composition containing the components (A), (B), and (C), and therefore have a low permittivity and a low dielectric loss tangent, and exhibit excellent electrical properties when a semiconductor device having such films is used in a high frequency region for, for example, fifth-generation mobile communications system “5G”, which is expected to be further increased in the capacity and transmission speed.

The resin composition of the embodiment of the present invention and the semiconductor device using the same can be used in electronic parts for electronic devices, such as a mobile phone, a smartphone, a laptop computer, a tablet terminal, and a camera module.

### EXAMPLES

Hereinbelow, the present invention will be described in more detail with reference to the following Examples. The present invention should not be limited by the Examples. In the following Examples and Comparative Example, the numbers indicating the formulation of each component contained in the resin composition are expressed in terms of the amount ((%) by mass), based on the mass of the resin composition (100% by mass), unless otherwise specified. When the resin composition contains only the components (A), (B), and (C) and does not contain an additive and the like, the mass of the resin composition means the total mass of the components (A), (B), and (C).

### Component (A): Modified Polyphenylene Ether (PPE) Resin

A-1: OPE 2st 1200 (modified polyphenylene ether resin having a vinyl group at both ends, and being represented by the formula (6) (reaction product of 2,2′,3,3′,5,5′-hexamethylbiphenyl-4,4′-diol/2,6-dimethylphenol condensation product and chloromethylstyrene); number average molecular weight (Mn): 1,200) (manufactured by Mitsubishi Gas Chemical Company, Inc.)
A-2: OPE 2st 2200 (modified polyphenylene ether resin having a vinyl group at both ends, and being represented by the formula (6) (reaction product of 2,2′, 3,3′,5,5′-hexamethylbiphenyl-4,4′-diol/2,6-dimethylphenol condensation product and chloromethylstyrene); number average molecular weight (Mn): 2,200) (manufactured by Mitsubishi Gas Chemical Company, Inc.)
A-3: NORYL SA9000 (modified polyphenylene ether resin having a methacryloyl group at both ends, and being represented by the formula (5), which has at the end a group represented by the formula (3); number average molecular weight (Mn): 1,850 to 1,950) (manufactured by SABIC Corporation) (manufactured by SABIC Innovative Plastics Japan LLC.)

### Component (B): Non-Hydrogenated Styrene/Butadiene/Styrene Block Copolymer (SBS)

B-1: Styrene/butadiene/styrene block copolymer (SBS) TR2827; styrene/butadiene ratio: 24/76 (%); number average molecular weight (Mn): 130,000 (manufactured by JSR Corporation).
B-2: Styrene/butadiene/styrene block copolymer (SBS) TR2003; styrene/butadiene ratio: 43/57 (%); number average molecular weight (Mn): 100,000 (manufactured by JSR Corporation).
B-3: Styrene/butadiene/styrene block copolymer (SBS) TR2250; styrene/butadiene ratio: 52/48 (%); number average molecular weight (Mn): 100,000 (manufactured by JSR Corporation).
B-4: Partially hydrogenated styrene/butadiene/butylene/styrene block copolymer (SBBS) P5051; styrene/butadiene ratio: 47/53 (%); number average molecular weight (Mn): 53,000 (manufactured by Asahi Kasei Chemicals Corporation)
B-5: Carboxylated nitrile butadiene rubber (NBR) Nipol (trademark) 1072, which has been modified with a carboxyl; number average molecular weight (Mn): 500,000 (manufactured by Zeon Corporation)

### Component (B′): Ethylene Tetrafluoride Resin

B′-6: Ethylene tetrafluoride resin Lubron (registered trademark) L-5F (manufactured by Daikin Industries, Ltd.).

### Component (C): Solvent

C-1: Toluene (manufactured by Daishin Chemical Co., Ltd.); boiling point: 110.6° C.
C-2: Anone (cyclohexanone, manufactured by Daishin Chemical Co., Ltd.); boiling point: 155.65° C.

### Additive: Organic Peroxide

PERBUTYL (registered trademark) Z (manufactured by NOF Corporation)

### Examples 1 to 12 and Comparative Example 1

The component (A), component (B) or component (B′), and component (C) were mixed and dissolved in a state at a constant temperature of 70° C. using a temperature-controlled water bath (SB-35, manufactured by Tokyo Rikakikai Co., Ltd.) and using a stirrer (SSR-112, manufactured by AGC Techno Glass Co., Ltd.), producing resin compositions in the Examples and Comparative Example. In Table 1, the symbol “-” indicates that the corresponding component is not contained in the resin composition. Further, in Table 1, “Mn” indicates a number average molecular weight.

TABLE 1

| | | Example | Example | Example | Example | Example | Example | Example |
|---|---|---|---|---|---|---|---|---|
| | | 1 | 2 | 3 | 4 | 5 | 6 | 7 |
| Component | A-1: Modified | — | — | — | 16 | — | — | — |
| (A) | polyphenylene ether | | | | | | | |
| | (Mn:1200) | | | | | | | |
| | A-2: Modified polyphenylene | 9.6 | 16 | 22.4 | — | 10 | 22.4 | 22.4 |
| | ether | | | | | | | |
| | (Mn:2200) | | | | | | | |
| | A-3: Modified polyphenylene | — | — | — | — | — | — | — |
| | ether | | | | | | | |
| | (Mn:1600) | | | | | | | |
| Component | B-1: Styrene/butadiene/ | — | — | — | — | — | 9.6 | — |
| (B) | styrene copolymer (SBS) | | | | | | | |
| | Styrene/butadiene ratio: | | | | | | | |
| | 24/76 | | | | | | | |
| | B-2: Styrene/butadiene/ | 22.4 | 16 | 9.6 | 16 | 10 | — | — |
| | styrene copolymer (SBS) | | | | | | | |
| | Styrene/butadiene ratio: | | | | | | | |
| | 43/57 | | | | | | | |
| | B-3: Styrene/butadiene/ | — | — | — | — | — | — | 9.6 |
| | styrene copolymer (SBS) | | | | | | | |
| | Styrene/butadiene ratio: | | | | | | | |
| | 52/48 | | | | | | | |
| | B-4: | — | — | — | — | — | — | — |
| | Styrene/butadiene/butylene/ | | | | | | | |
| | styrene copolymer (SBBS) | | | | | | | |
| | Styrene/butadiene ratio: | | | | | | | |
| | ′47/53 | | | | | | | |
| | B-5: Acrylonitrile/butadiene | — | — | — | — | — | — | — |
| | copolymer (NBR) | | | | | | | |
| Component | B′-6: Ethylene tetrafluoride | — | — | — | — | — | — | — |
| (B′) | resin | | | | | | | |
| Component | Toluene | — | — | — | — | — | — | — |
| (C) | Anone (Cyclohexanone) | 68 | 68 | 68 | 68 | 80 | 68 | 68 |
| Additive | Organic peroxide | — | — | — | — | — | — | — |

| | | | | | | | |
|---|---|---|---|---|---|---|---|
| Total | 100 | 100 | 100 | 100 | 100 | 100 | 100 |

| | | Example | Example | Example | Example | Example | Comparative |
|---|---|---|---|---|---|---|---|
| | | 8 | 9 | 10 | 11 | 12 | Example 1 |
| Component | A-1: Modified | — | — | — | — | — | — |
| (A) | polyphenylene ether | | | | | | |
| | (Mn:1200) | | | | | | |
| | A-2: Modified polyphenylene | 22.4 | 9.6 | — | 22.4 | 22.4 | 16 |
| | ether | | | | | | |
| | (Mn:2200) | | | | | | |
| | A-3: Modified polyphenylene | — | — | 22.2 | — | — | — |
| | ether | | | | | | |
| | (Mn:1600) | | | | | | |
| Component | B-1: Styrene/butadiene/ | 4.8 | — | — | — | — | — |
| (B) | styrene copolymer (SBS) | | | | | | |
| | Styrene/butadiene ratio: | | | | | | |
| | 24/76 | | | | | | |
| | B-2: Styrene/butadiene/ | — | 22.4 | 9.3 | — | — | — |
| | styrene copolymer (SBS) | | | | | | |
| | Styrene/butadiene ratio: | | | | | | |
| | 43/57 | | | | | | |
| | B-3: Styrene/butadiene/ | 4.8 | — | — | — | — | — |
| | styrene copolymer (SBS) | | | | | | |
| | Styrene/butadiene ratio: | | | | | | |
| | 52/48 | | | | | | |
| | B-4: | — | — | — | 9.6 | — | — |
| | Styrene/butadiene/butylene/ | | | | | | |
| | styrene copolymer (SBBS) | | | | | | |
| | Styrene/butadiene ratio: | | | | | | |
| | ′47/53 | | | | | | |
| | B-5: Acrylonitrile/butadiene | — | — | — | — | 9.6 | — |
| | copolymer (NBR) | | | | | | |
| Component | B′-6: Ethylene tetrafluoride | — | — | — | — | — | 16 |
| (B′) | resin | | | | | | |
| Component | Toluene | — | 68 | — | 14.7 | — | — |
| (C) | Anone (Cyclohexanone) | 68 | — | 68 | 53.3 | 68 | 68 |
| Additive | Organic peroxide | — | — | 0.5 | — | — | — |

| | | | | | | |
|---|---|---|---|---|---|---|
| Total | 100 | 100 | 100 | 100 | 100 | 100 |

### Evaluation of the Resin Composition

With respect to each of the resin compositions in the Examples and Comparative Example, a solubility and a viscosity were measured, and the results were shown in Table 3. In Table 3, with respect to Comparative Example 1 in which the component (B′) was not dissolved in the solvent as component (C), a coating film was not able to be formed, and therefore evaluation was impossible, and “NA” (Not Available) was shown in the table.

### Solubility

With respect to each of the resin compositions, the solubility of the component (A), and the component (B) or component (B′) in the solvent as component (C) at 70° C. was evaluated. A resin composition such that dissolution of the component (A), and the component (B) or component (B′) in the solvent as component (C) was visually observed clearly was rated “G (good)”, and a resin composition such that insolubility of the component in the solvent was visually observed clearly was rated “N (not-good)”.

### Viscosity

With respect to each of the resin compositions, using a TVE-type viscometer (cone rotor: 1° 34′ x R24; manufactured by Toki Sangyo Co., Ltd.), a first viscosity at 25° C. and at 10 rpm and a second viscosity at 25° C. and at 1 rpm were measured, and a thixotropy index TI (viscosity at 1 rpm/viscosity at 10 rpm), in terms of the ratio of the second viscosity to the first viscosity, was measured. Formation of an interlayer dielectric film

Using each of the resin compositions in the Examples and Comparative Example, a coating film which constitutes an interlayer dielectric film was formed, and subjected to heat treatment under the conditions shown below to cure the coating film formed of the resin composition, and, with respect to the resultant cured product, the following evaluations were conducted. The results were shown in Table 3.

### Thickness of the Interlayer Dielectric Film Formed by Spin Coating

The resin compositions in the Examples and Comparative Example were individually applied by spin coating to a silicon wafer having a diameter of 150 mm and a thickness of 0.525 mm as a semiconductor substrate using a spin coater (MS-A200, manufactured by Mikasa Co., Ltd.). In the spin coating, the spin coater was operated at 1,000 rpm for 5 seconds and then at 2,000 rpm for 30 seconds to apply the resin composition to the surface of the silicon wafer by spin coating, forming a coating film.

Further, the resin compositions in the Examples and Comparative Example were individually applied by spin coating to a silicon wafer having a diameter of 150 mm and a thickness of 0.525 mm as a semiconductor substrate using a spin coater (MS-A200, manufactured by Mikasa Co., Ltd.). In the spin coating, the spin coater was operated at 1,000 rpm for 5 seconds and then at 3,000 rpm for 30 seconds to apply the resin composition to the surface of the silicon wafer by spin coating, forming a coating film.

Subsequently, the silicon wafer having a thin film of the resin composition was subjected to heat pretreatment (drying) in a nitrogen gas atmosphere at 130° C. for 10 minutes, and heated to obtain a specimen having the dried coating film of the resin composition. Then, the obtained specimen was subjected to heat treatment (curing) in a nitrogen gas atmosphere at 200° C. for 60 minutes, obtaining a specimen having the cured coating film of the resin composition. A thickness of the coating film of the resin composition was measured by a stylus profiling system (Surfcom 300B, manufactured by Tokyo Seimitsu Co., Ltd.). The interlayer dielectric film can have a thickness of about 5 μm to 30 μm. The thickness of the interlayer dielectric film may be 5 μm or more, and may be 10 μm or more. Further, the thickness of the interlayer dielectric film may be 30 μm or less, and may be 20 μm or less.

### Warpage of the Semiconductor Substrate

With respect to the silicon wafer having a diameter of 150 mm and a thickness of 0.525 mm, which is a semiconductor substrate, a warpage of the silicon wafer itself (before application) was measured by means of a 3D thermal surface profiling apparatus (TherMoiré AXP 2.0, manufactured by Akrometrix, LLC) (hereinafter, referred to as “initial warpage”). With respect to each of the resin compositions in the Examples and Comparative Example, 3 g of the resin composition was applied dropwise onto the middle of the silicon wafer, and applied by spin coating using a spin coater (MS-A200, manufactured by Mikasa Co., Ltd.). In the spin coating, the spin coater was operated to apply the resin composition to the surface of the silicon wafer by spin coating, forming a coating film.

Subsequently, the silicon wafer having a thin film of the resin composition was subjected to heat pretreatment (drying) in a nitrogen gas atmosphere at 130° C. for 10 minutes, and heated to obtain a specimen having the dried coating film of the resin composition. Then, the obtained specimen was subjected to heat treatment (curing) in a nitrogen gas atmosphere at 200° C. for 60 minutes, obtaining a specimen having the cured coating film of the resin composition.

Then, using a 3D thermal surface profiling apparatus (TherMoiré AXP 2.0, manufactured by Akrometrix, LLC), a warpage of the silicon wafer was measured (hereinafter, referred to as “warpage after cured”). The warpage means a value (height) obtained by subtracting the initial warpage from the “warpage after cured”. Hereinafter, the silicon wafer is frequently referred to simply as “wafer”.

Warpage=(Warpage after cured)−(Initial warpage)

The warpage is preferably in the range of −5 mm to 5 mm, more preferably in the range of −3 mm to 3 mm, further preferably in the range of −2 mm to 2 mm. When the warpage of the wafer is in the range of −5 mm to 5 mm, the wafer can be held by adsorption using a wafer holding jig having a vacuum adsorption mechanism (for example, vacuum tweezers), and the wafer can be transferred to a desired position by moving the wafer holding jig. In contrast, when the wafer has a large warpage, the entire surface of the wafer cannot be adsorbed but, for example, only the center portion of the wafer is partially adsorbed. In this case, satisfactory holding force for the wafer cannot be obtained, leading to a disadvantage in that even a slight impact causes the wafer being transferred to be removed from the vacuum tweezers and fall. When the holding force is extremely small, it is likely that the wafer cannot be adsorbed.

### Measurement of Strength (Adhesion) (Cross-Cut Peel Test)

Strength (adhesion) was measured in accordance with ASTM D3359-97.

Specifically, the resin compositions in the Examples and Comparative Example were individually applied by spin coating to a silicon wafer having a diameter of 150 mm and a thickness of 0.525 mm as a semiconductor substrate using a spin coater (MS-A200, manufactured by Mikasa Co., Ltd.). In the spin coating, the spin coater was operated to apply the resin composition to the surface of the silicon wafer by spin coating, forming a coating film.

Subsequently, the silicon wafer having a thin film of the resin composition was subjected to heat pretreatment (drying) in a nitrogen gas atmosphere at 130° C. for 10 minutes, and heated to obtain a specimen having the dried coating film of the resin composition. Then, the obtained specimen was subjected to heat treatment (curing) in a nitrogen gas atmosphere at 200° C. for 60 minutes, obtaining a specimen having the cured coating film of the resin composition. Thus, a specimen for a cross-cut peel test was prepared.

Cross-cut lines in a lattice pattern were made as intersected in a cross in the surface of the prepared specimen having a coating film which functions as an interlayer dielectric film using a cross-cut guide (manufactured by COTEC Co., Ltd.), and then a self-adhesive cellulose tape (manufactured by Nichiban Co., Ltd.) was applied onto the resultant cross-cut portion of the specimen, and the cellulose tape was quickly peeled off from the specimen. An area of the coating film removed due to peeling was measured, and evaluated in a six scale of 0B to 5B shown in Table 2 below.

TABLE 2

| | Removed film area (%) |
|---|---|
| 5B | 0% |
| 4B | less than 5% |
| 3B | 5% or more, less than 15% |
| 2B | 15% or more, less than 35% |
| 1B | 35% or more, less than 65% |
| 0B | 65% or more |

### Relative Permittivity (ε) and Dielectric Loss Tangent (Tanδ)

A specimen for measurement was prepared as follows.

The resin compositions in the Examples and Comparative Example were individually applied to a support made of polyethylene terephthalate (PET), and subjected to heat pretreatment (drying) in a nitrogen gas atmosphere at 130° C. for 10 minutes, and heated to dry the resin composition, and subjected to treatment (curing) in a nitrogen gas atmosphere at 200° C. for 60 minutes, obtaining a coating film formed from the resin composition having a thickness of 10 μm.

A relative permittivity (ε) and a dielectric loss tangent (tanδ) of the specimen for measurement were measured at a dielectric resonance frequency of 5 GHz by a cavity resonator perturbation method. The relative permittivity (ε) is preferably 1.5 to 3.0, and the dielectric loss tangent (tanδ) is preferably 0.001 to 0.010.

TABLE 3

| | | Example | Example | Example | Example | Example | Example | Example |
|---|---|---|---|---|---|---|---|---|
| | | 1 | 2 | 3 | 4 | 5 | 6 | 7 |
| Solubility | Solubility | G | G | G | G | G | G | G |
| First viscosity | 25° C., 10 rpm | 3905 | 1567 | 629.9 | 1032 | 852 | 672 | 930 |
| (mPa · s) | | | | | | | | |
| Second viscosity | 25° C., 1 rpm | 3977 | 1571 | 692 | 1063 | 892 | 720 | 944 |
| (mPa · s) | | | | | | | | |
| Thixotropy | 1 rpm/10 rpm | 1.02 | 1.00 | 1.10 | 1.03 | 1.05 | 1.07 | 1.02 |
| index TI | | | | | | | | |
| Thickness (μm) | 1000 rpm/5 sec→ | 17 | 11 | 7 | 11 | 10 | 9 | 7 |
| | 2000 rpm/30 sec | | | | | | | |
| | 1000 rpm/5 sec→ | 12 | 8 | 5 | 8 | 7 | 7 | 5 |
| | 3000 rpm/30 sec | | | | | | | |
| 6-Inch wafer | Thickness (μm) | 12.0 | 12.0 | 11.5 | 11.0 | 10.0 | 9.0 | 13.0 |
| warpage (μm) | Warpage (μm) | −7.7 | 21.3 | 76.1 | 0.7 | 70.0 | 52.0 | 95.0 |
| Adhesion | Cross-cut peel | 5B | 5B | 5B | 5B | 5B | 5B | 5B |
| | test | | | | | | | |
| Relative | 5 GHz | 2.7 | 2.5 | 2.4 | 2.5 | 2.5 | 2.5 | 2.5 |
| Permittivity (ε) | | | | | | | | |
| Dielectric loss | 5 GHz | 0.0087 | 0.002 | 0.0024 | 0.002 | 0.002 | 0.002 | 0.002 |
| tangent (tanδ) | | | | | | | | |

| | | Example | Example | Example | Example | Example | Comparative |
|---|---|---|---|---|---|---|---|
| | | 8 | 9 | 10 | 11 | 12 | Example 1 |
| Solubility | Solubility | G | G | G | G | G | N |
| First viscosity | 25° C., 10 rpm | 1052 | 750 | 724 | 350 | 578 | NA |
| (mPa · s) | | | | | | | |
| Second viscosity | 25° C., 1 rpm | 1052 | 760 | 730 | 352 | 595 | NA |
| (mPa · s) | | | | | | | |
| Thixotropy | 1 rpm/10 rpm | 1.00 | 1.01 | 1.01 | 1.01 | 1.03 | NA |
| index TI | | | | | | | |
| Thickness (μm) | 1000 rpm/5 sec→ | 8 | 7 | 7 | 7 | 10 | NA |
| | 2000 rpm/30 sec | | | | | | |
| | 1000 rpm/5 sec→ | 6 | 6 | 6 | 6 | 8 | NA |
| | 3000 rpm/30 sec | | | | | | |
| 6-Inch wafer | Thickness (μm) | 8.0 | 10.0 | 7.0 | 4.0 | 10.0 | NA |
| warpage (μm) | Warpage (μm) | 73.5 | −6.0 | 28.0 | 6.9 | 33.0 | NA |
| Adhesion | Cross-cut peel | 5B | 5B | 5B | 5B | 5B | NA |
| | test | | | | | | |
| Relative | 5 GHz | 2.5 | 2.5 | 2.6 | 2.5 | 2.7 | NA |
| Permittivity (ε) | | | | | | | |
| Dielectric loss | 5 GHz | 0.002 | 0.002 | 0.002 | 0.002 | 0.013 | NA |
| tangent (tanδ) | | | | | | | |

As can be seen from Tables 1 and 3, with respect to each of the resin compositions in Examples 1 and 12, the solubility of the component (A) and component (B) in the component (C) was such excellent that a coating film having a substantially uniform thickness was able to be formed from the resin composition when applying the resin composition to a semiconductor substrate using a spin coater. Further, the coating films obtained from the resin compositions in Examples 1 to 12 had a relative permittivity (ε) of 2.7 or less and a dielectric loss tangent (tanδ) of 0.015 or less, and exhibited excellent electrical properties when a semiconductor device having such a coating film was used in a high frequency region for, for example, fifth-generation mobile communications system “5G”, which is expected to be further increased in the capacity and transmission speed.

Further, as can be seen from Tables 1 and 3, the resin compositions in Examples 1 to 12 had a first viscosity in the range of 300 to 4,000 mPa·s, as measured at 25° C. and at 10 rpm using a rotational viscometer, and had a second viscosity in the range of 500 to 4,200 mPa·s, as measured at 25° C. and at 1 rpm, and a thixotropy index TI was in the range of 0.8 to 1.2, in terms of the ratio of the second viscosity to the first viscosity. With respect to each of the resin compositions in Examples 1 to 9, a coating film having a substantially uniform thickness that has less unevenness was able to be formed from the resin composition when applying the resin composition to a semiconductor substrate using a spin coater, making it possible to suppress warpage of the semiconductor substrate during curing of the resin composition. Further, all the resin compositions in Examples 1 to 12 had such excellent adhesion that the evaluation in the cross-cut peel test was rated 5B, which indicates that the area of the removed coating film is 0%.

With respect to the resin composition containing an ethylene tetrafluoride resin in Comparative Example 1, the SEBS or ethylene tetrafluoride resin was not dissolved in the solvent as component (C), and it was impossible to apply the resin composition to a semiconductor substrate, and thus a coating film of the resin composition could not be formed.

### INDUSTRIAL APPLICABILITY

The resin composition of the present invention can be used in a WL-CSP type semiconductor device. The resin composition of the embodiment of the present invention and the semiconductor device using the same can be used in electronic parts for electronic devices, such as a mobile phone, a smartphone, a laptop computer, a tablet terminal, and a camera module.

1. A resin composition for a semiconductor device of a wafer level chip size package type, the resin composition comprising:
(A) a modified polyphenylene ether resin having an unsaturated double bond at the end thereof, and
(B) an elastomer having a butadiene skeleton.

2. The resin composition according to claim 1, wherein the modified polyphenylene ether resin (A) having an unsaturated double bond at the end thereof comprises a modified polyphenylene ether resin represented by the following formula (1): 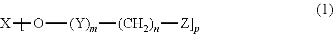
wherein X represents a p-valent unsubstituted or substituted aromatic hydrocarbon group,
Y represents an unsubstituted or substituted phenol repeating unit represented by the following formula (2): 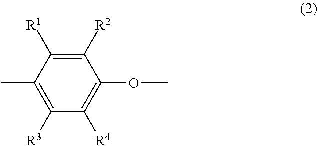
wherein each of R¹ to R⁴ independently represents a hydrogen atom, an alkyl group, an alkenyl group, an alkynyl group, or an alkenylcarbonyl group,
Z is a terminal functional group having a carbon-carbon double bond, and represents a vinyl group, a vinylene group, an (meth)acryloyl group represented by the following formula (3) or a styrene group represented by the following formula (4): 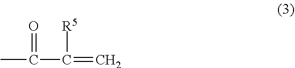
wherein R⁵ represents a hydrogen atom or an alkyl group, 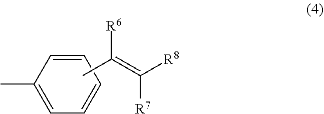
wherein each of R⁶ to R⁸ independently represents a hydrogen atom, an alkyl group, an alkenyl group, or an alkynyl group,
m represents an integer of 1 to 100,
n represents an integer of 0 or 1 to 6, and
p represents an integer of 1 to 4.

3. The resin composition according to claim 1, wherein the elastomer (B) having a butadiene skeleton comprises at least one member selected from the group consisting of a styrene/butadiene/styrene copolymer, a styrene/butadiene/butylene/styrene copolymer, a butadiene polymer, a styrene/butadiene copolymer, and an acrylonitrile/butadiene copolymer.

4. The resin composition according to claim 1, wherein the modified polyphenylene ether resin (A) having an unsaturated double bond at the end thereof comprises at least one member selected from the group consisting of a modified polyphenylene ether resin represented by the following formula (5) and a modified polyphenylene ether resin represented by the following formula (6): 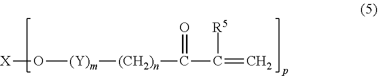
wherein R⁵ represents a hydrogen atom or an alkyl group,
X represents a p-valent unsubstituted or substituted aromatic hydrocarbon group,
Y represents an unsubstituted or substituted phenol repeating unit represented by the following formula (2): 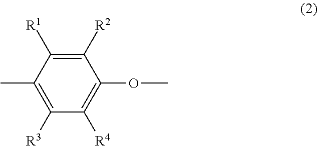
wherein each of R¹ to R⁴ independently represents a hydrogen atom, an alkyl group, an alkenyl group, an alkynyl group, or an alkenylcarbonyl group,
m represents an integer of 1 to 100,
n represents an integer of 0 or 1 to 6, and
p represents an integer of 1 to 4, 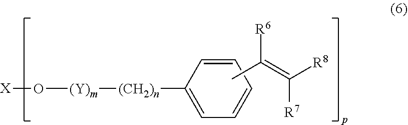
wherein each of R⁶ to R⁸ independently represents a hydrogen atom, an alkyl group, an alkenyl group, or an alkynyl group,
X represents a p-valent unsubstituted or substituted aromatic hydrocarbon group,
Y represents an unsubstituted or substituted phenol repeating unit represented by the formula (2) above,
m represents an integer of 1 to 100,
n represents an integer of 0 or 1 to 6, and
p represents an integer of 1 to 4.

5. The resin composition according to claim 1, wherein the elastomer (B) having a butadiene skeleton comprises at least one member selected from the group consisting of a styrene/butadiene/styrene block copolymer represented by the following formula (7) and an acrylonitrile/butadiene copolymer represented by the following formula (8): 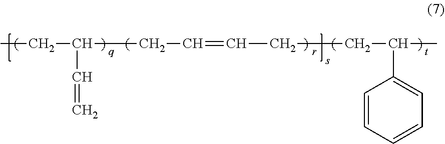
wherein q and r represent an integer of 0 or 1, with the proviso that at least one of q and r is not 0, s represents an integer of 1 to 1,200, and t represents an integer of 1 to 1,000, 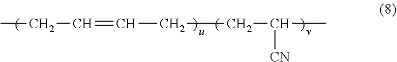
wherein u represents an integer of 1 to 1,200, and v represents an integer of 1 to 1,000.

6. The resin composition according to claim 1, wherein the modified polyphenylene ether resin (A) having an unsaturated double bond at the end thereof comprises a modified polyphenylene ether resin represented by the following formula (6): 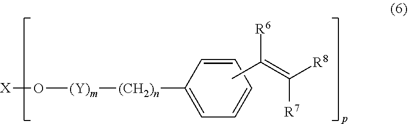
wherein each of R⁶ to R⁸ independently represents a hydrogen atom, an alkyl group, an alkenyl group, or an alkynyl group,
X represents a p-valent unsubstituted or substituted aromatic hydrocarbon group,
Y represents an unsubstituted or substituted phenol repeating unit represented by the following formula (2): 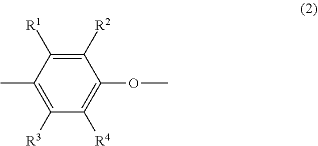
wherein each of R¹ to R⁴ independently represents a hydrogen atom, an alkyl group, an alkenyl group, an alkynyl group, or an alkenylcarbonyl group,
m represents an integer of 1 to 100,
n represents an integer of 0 or 1 to 6, and
p represents an integer of 1 to 4,
and wherein the elastomer (B) having a butadiene skeleton comprises a styrene/butadiene/styrene copolymer.

7. The resin composition according to claim 1, further comprising (C) a solvent.

8. The resin composition according to claim 7, which has a first viscosity in the range of 300 to 4,000 mPa·s, as measured at 25° C. and at 10 rpm using a rotational viscometer.

9. The resin composition according to claim 8, which has a second viscosity in the range of 500 to 4,200 mPa·s, as measured at 25° C. and at 1 rpm using a rotational viscometer, and which has a thixotropy index TI of 0.8 to 1.2, in terms of the ratio of the second viscosity to the first viscosity.

10. The resin composition according to claim 1, wherein the mass ratio of the component (A) and the component (B) is in the range of 10:90 to 80:20.

11. The resin composition according to claim 7, wherein the mass ratio of the total of the components (A) and (B) and the component (C) is in the range of 5:95 to 80:20.

12. A semiconductor device of a wafer level chip size package type,
the semiconductor device comprising a semiconductor substrate, an electrode disposed on the semiconductor substrate, a wiring electrically connected to the electrode, an external terminal electrically connected to the electrode through the wiring, and an interlayer dielectric film for encapsulating the side of the semiconductor substrate on which the electrode and the wiring are disposed,
wherein the interlayer dielectric film is disposed so as to be in contact with the wiring, and is formed using the resin composition according to claim 1.

13. The semiconductor device according to claim 12, which comprises at least two layers of a first interlayer dielectric film for encapsulating the semiconductor substrate side of the wiring and a second interlayer dielectric film for encapsulating the side of the wiring opposite to the semiconductor substrate.

14. The semiconductor device according to claim 12, wherein one layer of the interlayer dielectric film, the first interlayer dielectric film, and the second interlayer dielectric film has a thickness in the range of 3 to 20 μm.

15. A method for producing a semiconductor device of a wafer level chip size package type, the method comprising:
providing a resin composition in a liquid state, which comprises the following components (A) to (C):
(A) a modified polyphenylene ether resin having an unsaturated double bond at the end thereof,
(B) an elastomer having a butadiene skeleton, and
(C) a solvent;
applying dropwise the resin composition onto a semiconductor substrate and spinning the semiconductor substrate on the vertical axis using a spin coater to apply the resin composition in a liquid state to the semiconductor substrate; and
curing the resin composition in a liquid state to form an interlayer dielectric film.

16. The method for producing a semiconductor device according to claim 15, wherein the spin coater has a rotational speed of 1,000 to 3,000 rpm, and the time of rotation is 5 to 30 seconds.

17. The method for producing a semiconductor device according to claim 15, wherein the resin composition in a liquid state has a first viscosity of 300 to 4,000 mPa·s, as measured at 25° C. and at 10 rpm using a rotational viscometer.

18. The method for producing a semiconductor device according to claim 17, wherein the composition in a liquid state has a second viscosity of 500 to 4,200 mPa·s, as measured at 25° C. and at 1 rpm using a rotational viscometer, and has a thixotropy index TI of 0.8 to 1.2, in terms of the ratio of the second viscosity to the first viscosity.

19. The method for producing a semiconductor device according to claim 15, wherein the modified polyphenylene ether resin (A) having an unsaturated double bond at the end thereof comprises a modified polyphenylene ether resin represented by the following formula (1): 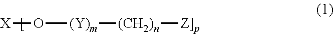
wherein X represents a p-valent unsubstituted or substituted aromatic hydrocarbon group,
Y represents an unsubstituted or substituted phenol repeating unit represented by the following formula (2): 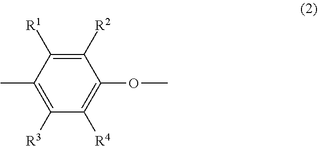
wherein each of R¹ to R⁴ independently represents a hydrogen atom, an alkyl group, an alkenyl group, an alkynyl group, or an alkenylcarbonyl group,
Z is a terminal functional group having a carbon-carbon double bond, and represents a vinyl group, a vinylene group, an (meth)acryloyl group represented by the following formula (3): 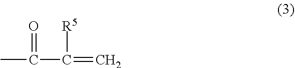
wherein R⁵ represents a hydrogen atom or an alkyl group,
or a styrene group represented by the following formula (4): 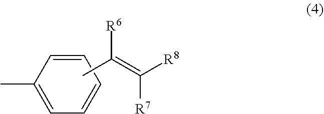
wherein each of R⁶ to R⁸ independently represents a hydrogen atom, an alkyl group, an alkenyl group, or an alkynyl group,
m represents an integer of 1 to 100,
n represents an integer of 0 or 1 to 6, and
p represents an integer of 1 to 4,
and wherein the elastomer (B) having a butadiene skeleton comprises at least one member selected from the group consisting of a styrene/butadiene/styrene copolymer, a styrene/butadiene/butylene/styrene copolymer, a butadiene polymer, a styrene/butadiene copolymer, and an acrylonitrile/butadiene copolymer.

20. The resin composition according to claim 7, wherein the mass ratio of the component (A) and the component (B) is in the range of 10:90 to 80:20.
